(19) United States
(12) Patent Application Publication
(10) Pub. No.: US 2015/0123263 A1
(43) Pub. Date: May 7, 2015

(54) TWO-STEP METHOD FOR JOINING A SEMICONDUCTOR TO A SUBSTRATE WITH CONNECTING MATERIAL BASED ON SILVER

(71) Applicant: Robert Bosch GmbH, Stuttgart (DE)

(72) Inventors: Christiane Frueh, Ludwigsburg (DE); Michael Guenther, Stuttgart (DE); Thomas Herboth, Ludwigsburg (DE)

(21) Appl. No.: 14/400,121

(22) PCT Filed: Apr. 2, 2013
(86) PCT No.: PCT/EP2013/056951

§ 371 Date: Nov. 10, 2014

(30) Foreign Application Priority Data
May 8, 2012 (DE) 10 2012 207 652.2

(51) Int. Cl. H01L 23/00

(52) U.S. Cl. CPC H01L 24/83; H01L 24/32; H01L 24/27; H01L 2224/32225; H01L 2224/8384; H01L 2224/83203; H01L 2224/831; H01L 2924/20101; H01L 2924/20102; H01L 2924/20103; H01L 2924/20104; H01L 2924/20105; H01L 2924/20106; H01L 2924/20107; H01L 2924/20108; H01L 2924/20109; H01L 2924/2011; H01L 2924/20111; H01L 2924/201; H01L 2924/01047; H01L 2224/2731
USPC 257/734; 228/225; 228/226

(57) ABSTRACT

The invention relates to a method for joining a semiconductor (20) to a substrate (10), comprising the following steps: •applying a first paste layer (1) of a sintering paste to the substrate; •heating and compressing the first paste layer to form a first sintered layer; •applying a second paste layer (2) of a sintering paste to the first sintered layer and arranging a semiconductor (20) on the second paste layer; •heating and compressing the second paste layer (2) to form a second sintered layer. The invention further relates to a semiconductor component produced by means of the method.

### BACKGROUND OF THE INVENTION

The invention relates to a method for joining a semiconductor to a substrate.

The standard method for obtaining joining connections in electronics is soldering. However, solders that are stable at high temperatures and can be used up to 240° C. are lead-based and can no longer be used in the future because of the toxicity of lead. Lead-free solders are tin-based. However, the temperature range within which they can be used has an upper limit of about 150° C. An alternative to soldered connections, in particular for the use of electronic connection technology in the high temperature range above 150° C., is that of sintered bonds based on silver. Apart from the basic capability of being able to be used at high temperatures, an advantage of these connections over soldering is the high resistance to changing temperatures.

Power-electronic components must be mounted on substrates, it being important because of the high currents to ensure good electrical and thermal coupling of the components to the substrate. The mentioned sintered connections on the basis of silver are produced by a silver-based paste comprising microparticles or nanoparticles being pressed together, the individual particles agglomerating to form a mechanically stable sintered layer and producing a stable mechanical connection between the two components adjoining the sintered layer, the substrate and the semiconductor component. To produce such a sintered layer, a silver paste is applied to a substrate with a metal surface. This is followed by a semiconductor, in particular a power diode or the like, being loaded onto the wet layer, followed by drying and driving out of the solvent at temperatures typically below 200° C. An alternative variant is that of loading a semiconductor onto the dried layer and establishing the sintered connection by exposure to an increased pressure.

Experience shows that the sintered layer often fails along the interface with the substrate, as can be demonstrated in particular by a corresponding peel test. The problem of this inadequate bond strength can be solved by raising the pressure in the sintering process. It has been found that the bond strength of the sintered layer correlates approximately linearly with the normal force in the sintering process. Therefore, the bond strength could be increased by raising the pressure in the sintering process. However, with pressures of the order of magnitude of 100 MPa in uniaxial pressing there is the problem that buffer materials, such as for example silicones, have to be used on the sintered contact for uniform pressure transfers. With buffer materials that are too soft, the pressure of 100 MPa cannot be transferred to the workpiece, so that it is necessary to change over to other pressing materials. With materials that are capable of transferring a pressure of 100 MPa, such as for example metals, there is however the risk of rupture of the semiconductor component.

DE 10 2009 008 926 A1 discloses a method for providing a connection between a subassembly semiconductor and a semiconductor device that is resistant to high temperatures and to changing temperatures, in which a metal powder suspension is applied to the regions of the individual semiconductor devices that are later to be connected, the suspension layer is dried while outgassing the volatile constituents and while producing a porous layer, the porous layer is pre-compacted, without a complete sintering that penetrates the suspension layer taking place, and, to obtain a strong connection of a semiconductor device that has good electrical and thermal conduction, the connection is a sintered connection produced without pressing pressure, by increasing the temperature, which consists of a dried metal powder suspension that has been provided in a pre-compaction step with a first transport-resistant contact with the part to which it is to be connected and has been densified without pressure by full thermal sintering.

US 2009/016 2557 A1 discloses a method for producing a sintered layer in which multiple layers are produced, just with drying of the suspension layer being carried out in each case.

### SUMMARY OF THE INVENTION

The invention provides a method for joining a semiconductor to a substrate comprises the following steps:
applying a first paste layer of a sintering paste to the substrate;
heating and compressing the first paste layer to form a first sintered layer;
applying a second paste layer of a sintering paste to the first sintered layer and arranging a semiconductor on the second paste layer;
heating and compressing the second paste layer to form a second sintered layer.

The underlying concept is consequently that of producing a first sintered layer at high pressure and/or high temperature on the substrate and then carrying out a further classic sintering process, by means of which a further layer is applied to the first sintered layer, involving applying the semiconductor, with the two sintered layers combining to form a connecting layer between the semiconductor and the substrate. Because of the high level of self-diffusion of micro- and nanocrystalline silver layers, the two separately produced sintered layers combine to form a dense connecting layer, without interfacial failure occurring because of the diffusion processes between the two sintered layers.

The paste layer is a layer of a sintering paste or suspension which is for example applied by screen printing or mask printing and can be sintered by exposure to pressure and temperature to form a solid sintered layer. The sintering paste or suspension is preferably a sintering paste or suspension containing silver particles for producing an electrically conductive and thermally conductive sintered layer based on silver.

Since the first sintered layer is applied without the semiconductor, sintering can be performed at much higher pressures and higher temperatures than would be possible with a semiconductor applied, since, as described above, there is the risk of the semiconductor being destroyed under excessively high pressures or the semiconductor losing its electronic functionality at temperatures that are for example significantly above 300° C. Since the first sintered layer is produced without the semiconductor, this can be performed at considerably higher pressures and temperatures, whereby a high-strength connection of the first sintered layer to the substrate is produced, allowing the risk of interfacial failure at the interface with the substrate to be overcome.

According to a further aspect of the invention, before the heating and compressing of the first and/or second paste layer, a drying of the paste layer is performed at a temperature of up to 200° C. In particular, an open drying of the paste layer may be carried out. The heating and compressing of the first paste layer is preferably performed at a higher pressure and/or at a higher temperature than the heating and compressing of the second paste layer.

The essence of the invention is consequently a two-step sintering method, wherein, in the first step, a sintered layer of low porosity and high mechanical strength and of high resistance to changing thermomechanical conditions is produced, by a sintering paste layer being applied to a substrate, for example by mask printing or screen printing. A drying step for driving out solvents may be carried out, in particular at temperatures below 200° C., in particular an open drying of the sintering paste layer, followed by carrying out a sintering of the paste layer by exposure to pressure and temperature to form a first sintered layer, in order to obtain a mechanically stable connection between the sintered layer and the substrate. In the second step, the bonding of the semiconductor is performed by way of a second sintered layer. In this case, a sintering paste layer is applied to the first sintered layer, for example by mask printing or screen printing, and the semiconductor is loaded onto the second sintering paste layer, followed by sintering of the paste layer by exposure to pressure and temperature to form a second sintered layer, to establish a mechanically stable and electrically and thermally conductive connection between the first sintered layer and the second sintered layer and also between the second sintered layer and the semiconductor component to be bonded on. In the sintering of the second paste layer to form the second sintered layer, the temperature and pressure range is in this case chosen such that the semiconductor component is not damaged. Before or after the loading of the semiconductor, but before the sintering of the second paste layer, a drying step for driving out solvents may be carried out, in particular at temperatures below 200° C.

The heating and compressing of the first paste layer may be performed at a temperature in the range from 200° C. to 600° C. and/or at a pressure in the range from 5 MPa to 120 MPa. The duration of the temperature and/or pressure exposure in the sintering of the first paste layer to form the first sintered layer may lie in the range from 10 seconds to 60 minutes. The heating and compressing of the second paste layer may be performed at a temperature of 150° C. to 400° C. and/or at a pressure of 5 MPa to 40 MPa, in particular for a duration of 10 seconds to 60 minutes. It should be noted that the heating and compressing of the second paste layer to form the second sintered layer with the loaded semiconductor component is performed in a pressure and temperature range with which damage to the semiconductor component can be ruled out.

The particular advantage of the invention is that in the production of the first sintered layer it is not necessary to consider and maintain maximum exposures to pressure or temperatures due to an applied semiconductor component, since only a first sintered layer of low porosity and high mechanical quality has to be produced on the substrate. The two-step method according to the invention has the effect of shifting the maximum stresses occurring in the connecting layer from the peripheral region of the bonding of the sintered layer to the substrate into the central region of the sintered layers, and a high-strength connection of the sintered layer to the substrate is produced by exposure to a high temperature and/or pressure in the first sintering step, whereby failure of the sintered layer in the boundary region of the sintered layer to the substrate can be ruled out. As a result, the weak point of the sintered layer connection that experience shows dominates in the prior art is eliminated.

According to a further aspect of the invention, the first sintered layer has a lower porosity than the second sintered layer. Repeated application of a paste layer of a sintering paste to the lower sintered layer and subsequent heating and compressing of the paste layer allow more than two sintered layers to be produced, the semiconductor being applied to the uppermost paste layer, followed by heating and compressing of the uppermost paste layer to form the uppermost sintered layer. In particular, according to a further aspect of the invention, three sintered layers may be produced, it being possible for the middle sintered layer to be structured. Layers of different thicknesses, porosities and specific compositions and/or different lateral dimensions may be produced. It is possible to produce the connection between the substrate and the semiconductor from more than two printed sintering paste layers or sintered layers, in particular comprising three sintered layers, it being possible for one or more sintered layers to be structured, and the semiconductor being applied to the uppermost layer of the sintering paste. Furthermore, the sintering pastes of the various paste layers may have different compositions, in particular different additives.

Furthermore, one or more sintered layers may be configured in such a way that the sintered layer has a higher area coverage density of the sintering elements in the middle of the contact area, it being possible for the area coverage density of the sintering elements to be lower at the periphery of the contact area than in the middle, whereby the reliability of the sintered connection in the peripheral region is further increased. The high area coverage density of the sintering elements in the middle of the contact area has in turn the effect of ensuring good thermal and electrical conductivity in the regions in which the development of a high temperature typically occurs during the operation of the semiconductor component.

The area coverage density of the sintering elements on the substrate may however also be formed in such a way that, from the middle region of the contact area to the peripheral region, the area coverage density is increased in the direction of the peripheral region, in order in particular to strengthen the peripheral region of the sintered connection and counter crack formation. It is consequently possible, by specifically predetermining the particle distribution within the sintering paste layer to be applied, to predetermine different porosities and structural properties within each sintered layer.

### BRIEF DESCRIPTION OF THE DRAWINGS

The invention and advantageous configurations according to the features of the further claims are explained in more detail below on the basis of the embodiment that is represented in the drawing, in which:

FIG. 1 shows the application of a first layer to the substrate;

FIG. 2 shows the application of a second layer of a sintering paste to the first sintered layer and the loading of a semiconductor onto the second paste layer to produce the connection of the semiconductor to the substrate.

### DETAILED DESCRIPTION

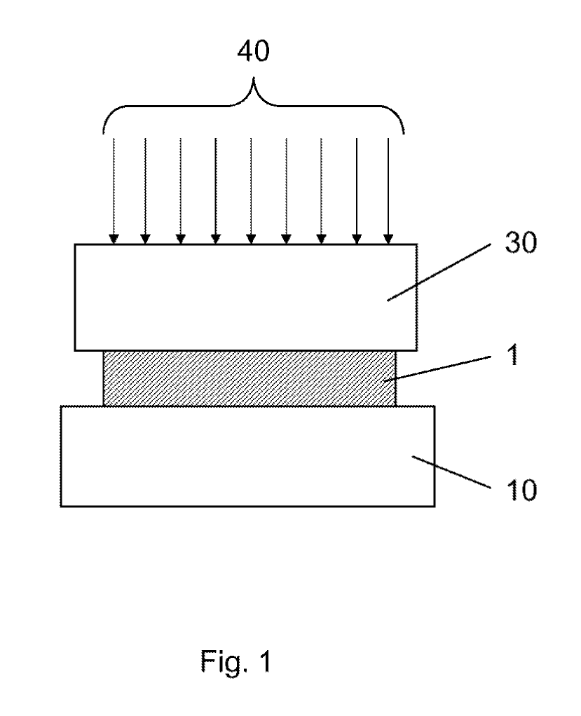

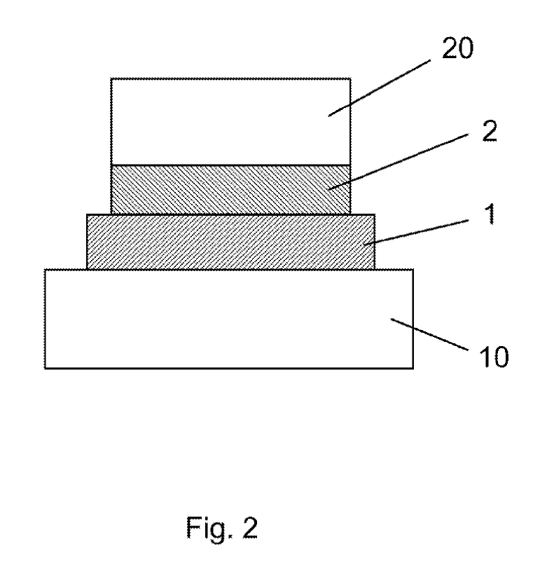

On the basis of FIGS. 1 and 2, the method according to the invention for joining a semiconductor to a substrate is explained below. In FIG. 1, a substrate 10 is shown. The substrate 10 may be a metal substrate, in particular a copper substrate or a substrate coated with metal. This substrate may in particular have a precious metal surface, for example by a nickel-gold metallization. A first layer of a silver paste 1 is applied to the substrate 10 by mask printing or screen printing. This is followed by an open drying of the silver paste layer 1 for driving out the solvent. This open drying is performed at temperatures below 200° C.

By exposing the paste layer 1 to a pressure in the range from 5 to 120 MPa and a temperature of 200° C. to 600° C. for a duration of 10 seconds to 60 minutes, the first sintered layer 1 is produced. This involves using the pressing tool 30, in order to compress and sinter the layer. The pressure exposure of the sintering paste layer 1 during the sintering to form the first sintered layer 1 is indicated by the arrows 40. The exposure of the first layer 1 to very high pressure and temperature has the effect of producing a stable connection between the sintered layer 1 and the substrate 10. The sintering paste consists of micro- and/or nanoparticles with silver as the main constituent.

Since no semiconductor has been applied as yet to the first layer 1, a very high pressure can be produced by means of the tool 30 during the sintering, since there is no risk of damage to a semiconductor, so that a very strong connection is produced between the sintered layer 1 and the substrate 10.

In FIG. 2, the further step of producing the connection of the semiconductor 20 to the substrate 10 by way of the sintered layers 1 and 2 is shown. After the sintering of the first layer 1, a silver paste is applied to the first sintered layer 1 by mask printing or screen printing to produce a second layer 2. The loading of the semiconductor 20 is performed into the wet layer 2. The semiconductor 20 may be for example a power transistor, a power diode or some other power component. In particular, the semiconductor 20 may be a MOSFET, an IGBT, a JFET, a BJT, a switchable thyristor or a similar component, or comprise such a component.

Before the sintering of the second paste layer to form a second sintered layer 2, a drying of the second layer may be performed for driving out the solvent. This is followed by a sintering of the second paste layer with exposure to pressure and temperature for a duration of 10 seconds to 60 minutes, according to requirements, to form the second sintered layer 2, the pressure and temperature exposure being chosen such that the semiconductor 20 is not in any way damaged. A pressure of up to 40 MPa may be provided here as the pressure range, and a temperature in the range from 150° C. to 400° C., depending on the compatibility of the semiconductor 20. Overall, the sintering of the second sintered layer 2 is performed at the same or a lower pressure and/or at the same or a lower temperature than the sintering of the first sintered layer 1, so that the first and second sintered layers may have different grain sizes because of the grain growth under the influence of temperature.

In the first step, which was explained on the basis of FIG. 1, the production of a first sintered layer 1 of low porosity and high mechanical strength and high resistance to changing thermomechanical conditions is consequently performed.

Then, in a second step, as explained on the basis of FIG. 2, the semiconductor 20 is connected to the first sintered layer 1 by way of a second sintered layer 2, and is thereby joined to the substrate 10.

The very high pressure and the very high temperature in the sintering process for producing the first sintered layer 1 have the effect that the bond strength of the first sintered layer 1 on the substrate 10 is significantly increased by an increase in size of the effective contact area between the silver particles of the first sintered layer 1 and the surface of the substrate 10. Because of the high self-diffusion of the micro- or nanocrystalline sintered layers 1, 2 based on silver, interfacial failure between the two sintered layers 1, 2 is ruled out, and a reliable connection between the two sintered layers 1, 2 is obtained for the bonding of the semiconductor 20 to the substrate 10.

The semiconductor components produced by the method according to the invention, i.e. the semiconductor components in which the semiconductor 20 has been joined to the substrate 10 by the multi-step method according to the invention, is suitable in particular for use in components that are subjected to high temperatures, high currents or changing temperatures, it being possible for a wide variety of electronic and power-electronic components to be joined to a substrate. Joining of large-area connections of semiconductors 20 to a substrate 10 is also possible, in particular for heat removal, if a substrate 10 is arranged on a heat dissipating plate.

1. A method for joining a semiconductor to a substrate (10), comprising the steps of:
applying a first paste layer (1) of a sintering paste to the substrate (10);
heating and compressing the first paste layer (1) to form a first sintered layer;
applying a second paste layer (2) of a sintering paste to the first sintered layer (1) and arranging a semiconductor on the second paste layer (2); and
heating and compressing the second paste layer (2) to form a second sintered layer.

2. The method as claimed in claim 1, characterized in that, before the heating and compressing of one of the first paste layer and the second paste layer (1, 2), a drying of the one of the first paste layer and the second paste layer (1, 2) is carried out at a temperature of up to 200° C., in particular an open drying is carried out.

3. The method as claimed in claim 1, characterized in that the heating and compressing of the first paste layer (1) is performed at at least one of a higher pressure and a higher temperature than the heating and compressing of the second paste layer (2).

4. The method as claimed in claim 1, characterized in that the heating and compressing of the first paste layer (1) is performed at a temperature from 200° C. to 600° C.

5. The method as claimed in claim 1, characterized in that the heating and compressing of the second paste layer (2) is performed at a temperature from 150° C. to 400° C.

6. The method as claimed in claim 1, characterized in that the first sintered layer (1) has a lower porosity than the second sintered layer (2).

7. The method as claimed in claim 1, characterized in that more than two sintered layers (1, 2) are produced by repeated application of an applied paste layer (1, 2) of a sintering paste to a lower sintered layer and subsequent heating and compressing of the applied paste layer (1, 2), the semiconductor being applied to an uppermost paste layer, followed by heating and compressing of the uppermost paste layer to form an uppermost sintered layer.

8. The method as claimed in claim 1, characterized in that three sintered layers are produced, one or more sintered layer(s) being structured.

9. The method as claimed in claim 1, characterized in that the sintering pastes of the various paste layers have different compositions.

10. A semiconductor component, comprising a semiconductor joined to a substrate by a method as claimed in claim 1.

11. The method as claimed in claim 1, characterized in that, before the heating and compressing of one of the first paste layer and the second paste layer (1, 2), an open drying of the one of the first paste layer and the second paste layer (1, 2) is carried out at a temperature of up to 200° C.

12. The method as claimed in claim 1, characterized in that the heating and compressing of the first paste layer (1) is performed at a pressure from 5 MPa to 120 MPa.

13. The method as claimed in claim 1, characterized in that the heating and compressing of the first paste layer (1) is performed at a temperature from 200° C. to 600° C. and at a pressure from 5 MPa to 120 MPa.

14. The method as claimed in claim 1, characterized in that the heating and compressing of the first paste layer (1) is performed at a temperature from 200° C. to 600° C. and at a pressure from 5 MPa to 120 MPa for a duration of 10 s to 60 min.

15. The method as claimed in claim 1, characterized in that the heating and compressing of the second paste layer (2) is performed at a pressure from 5 MPa to 40 MPa.

16. The method as claimed in claim 1, characterized in that the heating and compressing of the second paste layer (2) is performed at a temperature from 150° C. to 400° C. and at a pressure from 5 MPa to 40 MPa.

17. The method as claimed in claim 1, characterized in that the heating and compressing of the second paste layer (2) is performed at a temperature from 150° C. to 400° C. and at a pressure from 5 MPa to 40 MPa for a duration of 10 s to 60 min.

18. The method as claimed in claim 17, characterized in that the heating and compressing of the first paste layer (1) is performed at a temperature from 200° C. to 600° C. and at a pressure from 5 MPa to 120 MPa for a duration of 10 s to 60 min.

19. The method as claimed in claim 1, characterized in that the sintering pastes of the various paste layers have different additives.
